(19) United States
(12) Patent Application Publication
(10) Pub. No.: US 2010/0288525 A1
(43) Pub. Date: Nov. 18, 2010

(54) ELECTRONIC PACKAGE AND METHOD OF MANUFACTURE

(75) Inventors: Nagesh Basavanhally, Skillman, NJ (US); Christopher DW. Jones, Millington, NJ (US)

Correspondence Address: HITT GAINES, PC;ALCATEL-LUCENT, PO BOX 832570, RICHARDSON, TX, 75083, US

(73) Assignee: Alcatel-Lucent USA, Incorporated, Murray Hill, NJ (US)

(21) Appl. No.: 12/464,461

(22) Filed: May 12, 2009

(51) Int. Cl. H05K 5/06; B32B 37/06; B29C 65/24

(52) U.S. Cl. 174/50.52; 156/274.4; 156/273.9

(57) ABSTRACT

An apparatus that comprises an electronic device package 102. The package includes an electronic device 105 on a first planar substrate 110, and, a second planar substrate 112 bonded to the first planar substrate so as to form an interior chamber 115 housing the electronic device. The package includes a plurality of electrically conductive pins 120, each of the pins passing through a hole 125 in one of the first and second planar substrates. A first end 130 of each pin is located in the interior chamber and is electrically coupled to the electronic device. A second end 132 of each pin is located on an exterior side 135 of the one of the first and second substrates. An inorganic sealant 140 surrounds at least one of the first end or the second end for each of the pins.

### TECHNICAL FIELD

This application is directed, in general, to electronic device packaging and, more specifically, to a sealed electronic device package, and, to methods of manufacturing such packages.

### BACKGROUND

This section introduces aspects that may help facilitate a better understanding of the inventions. Accordingly, the statements of this section are to be read in this light and are not to be understood as admissions about what is prior art or what is not prior art.

For many electrical applications, it is desirable to package an electronic device inside a sealed chamber. It is still necessary, however, to provide external electrical connections between the device and other devices that are external to the sealed device package. Some processes to manufacture sealed device package are material intensive and time consuming thereby increasing the cost of the resulting sealed device package. Moreover, the external electrical connections may not be properly sealed or may lose their seal causing the entire chamber to lose its seal. This, in turn, can cause the device to malfunction or fail earlier than its expected product lifetime.

### SUMMARY

One aspect of the disclosure provides an apparatus that comprises an electronic device package. The package includes an electronic device on a first planar substrate, and, a second planar substrate bonded to the first planar substrate so as to form an interior chamber housing the electronic device. The package includes a plurality of electrically conductive pins, each of the pins passing through a hole in one of the first and second planar substrates. A first end of each pin is located in the interior chamber and is electrically coupled to the electronic device. A second end of each pin is located on an exterior side of the one of the first and second substrates. An inorganic sealant surrounds at least one of the first end or the second end for each of the pins.

Another embodiment is a method. The method comprises providing a first planar substrate with a plurality of electronic devices thereon. The method comprises providing a second planar substrate, one of the first and second substrates having a plurality of holes there through. The method comprises forming electrically conductive pins that traverse the holes such that a portion of each pin is surrounded by an inorganic sealant. The method comprises bonding the second substrate to the first substrate to form a chamber housing one or more of the electronic devices, first ends of the pins protruding to an exterior of the chamber and second ends of the pins making electrical contact with the one or more the electronic devices.

### BRIEF DESCRIPTION OF THE DRAWINGS

The various embodiments can be understood from the following detailed description, when read with the accompanying figures. Various features may not be drawn to scale and may be arbitrarily increased or reduced in size for clarity of discussion. Reference is now made to the following descriptions taken in conjunction with the accompanying drawings, in which:

FIG. 1 presents a cross-sectional view of an example embodiment of a sealed electronic device package of the disclosure;

FIG. 2 presents a cross-sectional detail view of a portion of the example embodiment presented in FIG. 1;

FIGS. 3A and 3B present a cross-sectional views of second and third example embodiments of a sealed electronic device package of the disclosure;

FIGS. 4-10 present cross-sectional views at selected stages in one example of a method to manufacture an electronic apparatus which includes a sealed electronic device package, e.g., as illustrated in FIGS. 1-3, and, shows embodiments of an apparatus that includes example device packages.

### DETAILED DESCRIPTION

The present disclosure presents an electronic device package that may be formed while electronic devices are coupled to a common single substrate. It was discovered that the cost and reliability of a sealed electronic device package can be improved by performing packaging steps while several electronic devices are still coupled to the same substrate. This is in contrast with certain labor and time consuming packaging processes that package individual electronic devices after they have been made and separated from each other on the substrate.

Additionally, as part of the disclosed packaging process, electrical connections from the package to devices external to the package include electrically conductive pins and an inorganic sealant. The pins provide a reliable conductive path, and, the inorganic sealant facilities forming and retaining a sealed package (e.g., hermetically sealed package). This is in contrast with certain packaging processes that use an electrochemical process to form electrical connections. Such an electrochemical process to form external electrical connections can include metal seed layer deposition followed by the electro-deposition of metal into through-holes. In addition to being costly and time consuming, the electrochemical process can result in some holes being partially filled. Thus, the chamber's vacuum or special atmosphere can be lost due to gases being able to leak through voids in the holes that are not sealed, when electro-deposited metal is used to form such through-substrate electrical connections.

One embodiment is an apparatus comprising a sealed electronic device package. The electrical apparatus could be an electrical apparatus component of a telecommunications system that uses a sealed electronic device package. Non-limiting examples of other electrical apparatus include magnetometers, light sensors (e.g., infrared sensors, visible light sensors), accelerometers, spatial light modulators, microelectromechanical system (MEMS) and/or optoelectronic (OE) devices of integrated circuits (IC), that could include the device package.

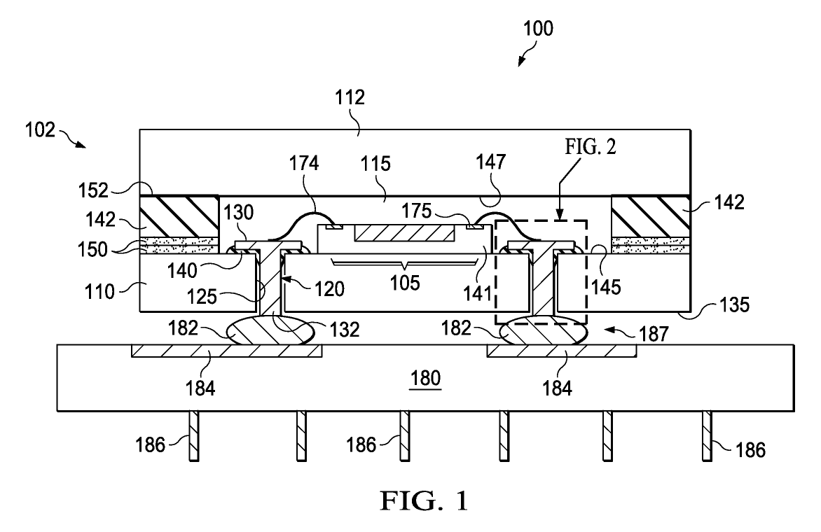

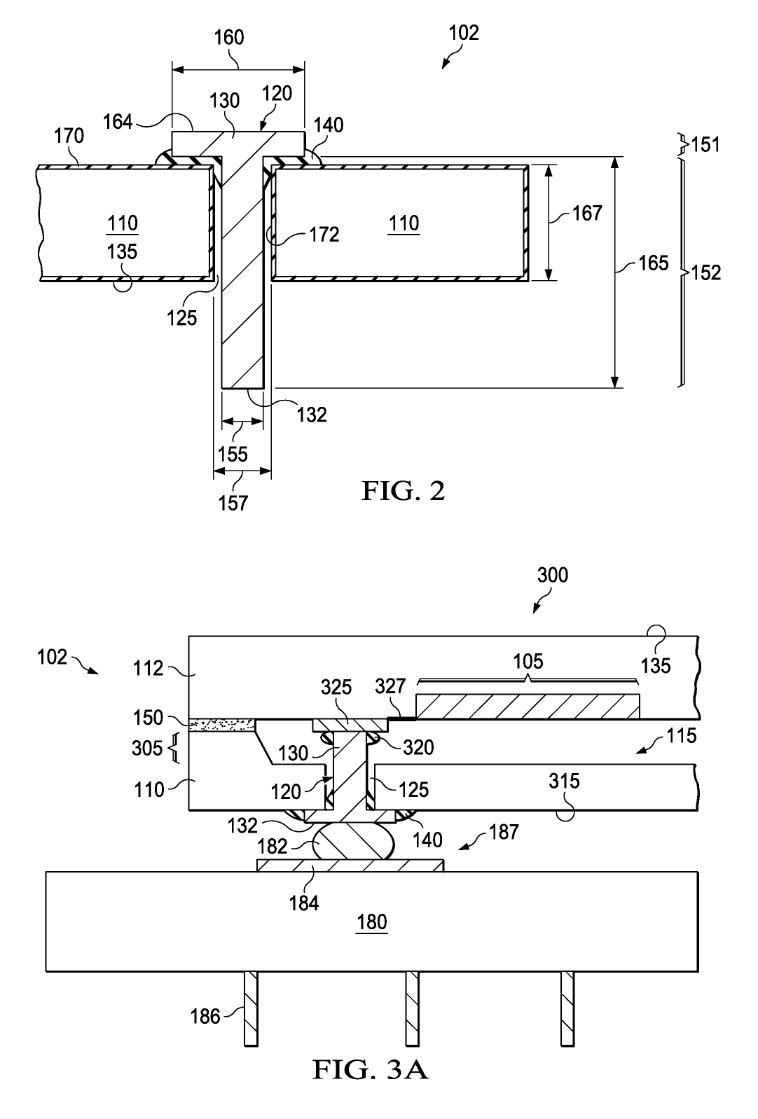

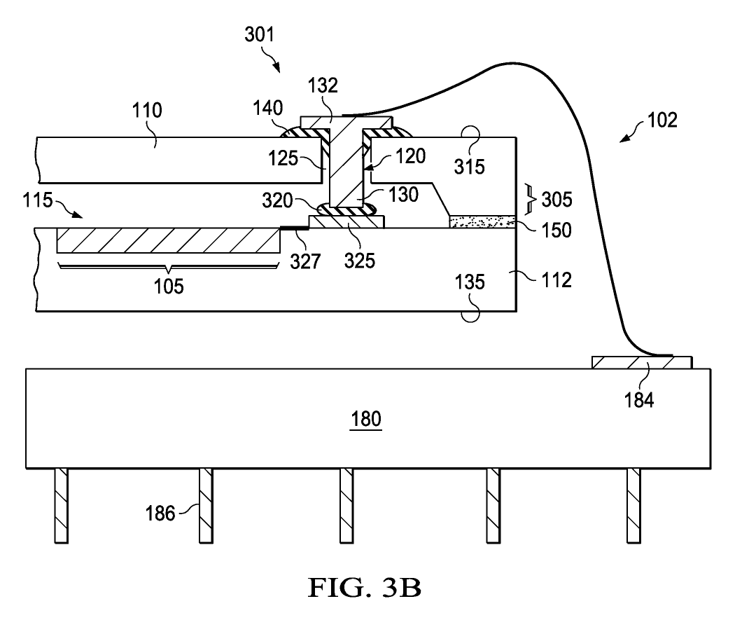

FIG. 1 presents a cross-sectional view of an example embodiment of an apparatus 100 comprising an electronic device package 102 of the disclosure. Preferably the package is a sealed package 102. FIG. 2 presents a detail view of a portion of the package 102 depicted in FIG. 1. Second and third example apparatuses 300, 301 are presented in FIGS. 3A and 3B, respectively to illustrate certain alternative package configurations and features. For clarity, the same reference numbers are used to show similar package features for all of the figures.

As illustrated in FIG. 1, the package 102 includes an electronic device 105 located on or in a first substrate 110, and a second substrate 112, bonded to the first substrate 110 so as to form an interior chamber 115 housing the electronic device 105. As illustrated in FIG. 1, in some cases, one or both of the first and second substrates 110, 112 are planar substrates. The package 102 also includes a plurality of electrically conductive pins 120. Each of the pins 120 passes through one a hole one of the first substrate 110 or second substrate 112. There can be a plurality of holes 125 in one or both of the substrates 110, 112 and one pin 120 passing through one of the holes 125. A first end 130 of each pin 120 is located in the interior chamber 115 and is electrically coupled to the electronic device 105. A second end 132 of each pin 120 is located on an exterior side 135 of the substrate 110, 112 having the holes 125 (e.g., the first substrate 110 in FIG. 1). An inorganic sealant 140 surrounds at least one of the ends 130, 132 of each of the pins 120 (e.g., the first end 130 of the pins 120 in FIG. 1). Preferably, the sealant surrounds the pin 120 such that the hole 125 is sealed.

The electronic device 105 could include one or more devices that are manufactured on or in the substrate (e.g., the first substrate 110). In some embodiments, the devices 105 are separately manufactured on a separate substrate 141 and then mounted on the single common substrate 110. The electronic device 105 could be an IC, a MEMS device, OE element (e.g., photon detectors, infrared detectors), or, combinations thereof. At least a portion of the substrate 110 forms part of the package 102.

At least one of the substrates 110, 112 is composed of a solid material that is conducive to the manufacture or mounting of the device 105 thereon. Additionally, both substrates 110, 112 are composed of solid materials that can form a gas-impervious or vacuum seal. In some preferred embodiments, the substrates 110, 112 are composed of materials that can be molded, patterned or implanted with dopants to facilitate fabricating the device 105 on or in the substrate 110. Such materials can also facilitate shaping or patterning one or both of the substrates 110, 112 to define the chamber 115 or form the holes 125. Example substrate materials include metals (e.g., aluminum, or brass), inorganic semiconductors (e.g., silicon, gallium arsenide), or inorganic insulators (e.g., silicon oxide, lithium niobate). Substrates composed only of metal may not be desirable in some embodiments where electrical connection could contact the substrate. In such cases, however, an electrically insulated metal substrate could be used. Certain porous materials or organic materials, such as plastics, are generally excluded as substrates because gases (e.g., air) can pass through them. It is possible to use such materials, however, if their outer surface can be entirely covered with a gas-impervious material (e.g., a plastic layer coated with a metal foil). In some cases it is desirable for the substrates 110, 112 to be composed of the same material because this minimizes thermal mismatches that otherwise impart stress that could detrimentally affect the performance of the device 105.

As noted above, in some preferred embodiments, portions of the first substrate 110 are components of the electronic device 105. That is, parts of the first substrate 110 are used to fabricate component parts that are necessary to the operation of the electronic device 105. Some of these embodiments have the advantage of facilitating package's 102 formation as a part, or an extension, of substrate-level (e.g., wafer-level) device processing. Some of these embodiments of the device 105 components and substrate 110 have the same the same thermal expansion coefficient. This is in contrast to the ceramic packaging a silicon-based device 105, where it can be difficult to find a ceramic material with matching thermal characteristics. A sufficient mismatch in the thermal expansion coefficient device 105 and substrate 110 can cause the device to become separated from the substrate 110 during thermal stresses experienced during the package's 102 manufacture, handing or end use.

In other cases, however, the electronic devices 105 are separately made and then mounted to one of the substrates 110, 112. This may be an advantage when processes to construct the device 105 on or in the substrate 110 are incompatible with other steps in the packaging process. E.g., in some cases, high temperature process steps used to form the holes 125, or, to seal the pins 120 in the holes 125, may damage an IC, MEMS or OE device 105. To avoid this, the holes 125 can be formed and the pins 125 sealed, before the devices 105 are mounted on the substrate 110. Alternatively, as illustrated for the embodiment shown in FIG. 3B, the holes 125 and pins 120 can be formed in a second substrate 112, and the device 105 formed in or on, or mounted to, the first substrate 110.

As illustrated in FIG. 1, in some cases, additional substrates can be used to help define the chamber 115. For instance, separately made spacer substrates 142 can be located in-between, and bonded to both of the substrates 110, 112, so as to separate their opposing surfaces 145, 147.

In some cases, instead of using a separate spacer substrate, one of the substrates is configured to have spacer structures built-in. For example, FIGS. 3A and 3B shows embodiments where a portion of the second substrate 112 has been removed to define part of the chamber 115, and, to define spacer portions 305 of the second substrate 112 that are bonded to the first substrate 110. One advantage of this approach is that only two substrates are used to form the chamber 115, thereby avoiding the need to manufacture multiple substrates and then bond them together.

It can be important for the bond between substrates 110, 112, 142 to be a gas-impervious bond so that a sealed chamber 115 is formed. In some preferred embodiments, a bonding agent is used to seal the substrates together. For instance, FIG. 1 shows an embodiment where a bonding agent 150 is used to bond the first and second substrates 110, 112 together through the spacer substrate 142. For example, in some preferred embodiments a bonding agent 150 of solder or sintered glass is placed on one or both of the first substrate 110 and spacer substrate 142. The bonding agent 150 is melted to bond the substrates 110, 142 together and form a gas impervious seal. Certain organic adhesives, such as epoxy glues, are inappropriate to use as bonding agents because gases can diffuse though the organic adhesive during, or even after it's curing.

In some cases, it is advantageous for one of the first or seconds substrates 110, 112 to be, or include, a semiconductor layer, and, the other of the first or second substrate 110, 112, to be, or include, a glass layer. For instance, using a transparent glass substrate allows the packaged device 105 to be inspected for proper functioning. For instance, the device 105 (e.g., configured as a light sensor) communicates with other devices external to the package through the glass substrate.

The combination of semiconductor and glass substrates 110, 112, can sometimes also be conducive to forming an anodic bond between the substrates. Forming an anodic bond can remove the need to use a bonding agent. For instance, FIG. 1 shows an embodiment where an anodic bond 152 is used to bond the second substrate 112 to the spacer substrate 142. The anodic bond can be formed by passing a voltage between the two substrates of specific chemical compositions at an elevated temperature. For example, a first substrate 110 composed of silicon and a second substrate composed of sodium-rich glass (e.g., about 3 wt % sodium or higher) are conducive to forming an anodic bond.

In some preferred embodiments, the interior chamber 115 is vacuum-sealed or hermetically-sealed from an external environment (e.g., air or water) surrounding the package 105. In some cases, a vacuum or hermetic seal is necessary for the proper function of the electronic device 105 over the length of its intended life-time. For the purposes of the present disclosure, a vacuum-sealed interior chamber 115 is defined as having a pressure of about 1 mTorr or lower. A hermetically-sealed interior chamber 115 is defined as in MIL-Std-883 document, which is incorporated by reference herein in its entirety. One of ordinary skill in the art would be familiar with the equipment and procedures to measure the extent of vacuum or hermeticity present in a sealed chamber. A gas impervious material permits the retention of the vacuum or hermetic seal of the chamber 115 for the lifetime of the package 102.

As shown in FIG. 2 some preferred pin 120 structures include a head portion 151 and a body portion 152. To facilitate forming a hermetic or vacuum seal, in some cases, the pins 120 have a body diameter 155 that is about 90 to 99 percent of the diameter 157 of the hole 125 through which it is placed (FIG. 2, partial expanded view). In some cases, one end (e.g., first end 130) of the pins 120 has a head diameter 160 that is in a range of about 200 to 300 percent larger than the diameter of the of the hole 125. For instance, in some embodiments, when the hole diameter 157 equals about 0.3 mm, the body diameter is about 0.25 mm and the head diameter 160 is about 0.76 mm.

The pin's head diameter 160 is carefully selected to provide one or more beneficial features. The head diameter 160 is large enough to prevent the pins 120 from passing entirely through the holes 125. In some cases, the head diameter 160 large enough to provide bonding locations for the sealant 140 on the head surface 164 that faces the substrate 110 that the pin 120 is passed through, and, to provide locations for the electrical connections to be formed to the device 105 or external devices, on the head surface 164 that faces away from the substrate 110 that it passes through. The head diameter 160 is small enough to not cover up a substantial amount of the substrate 110 because this would provide to accommodate the device 105 and the package's 102 size could be unnecessarily large.

Having the pin's ends 132 above the substrate's surface 135 can facilitate forming an electrical connection to the pin 120. In some embodiments, the pin 120 bodies 152 are long enough to pass entirely through the substrate 110 so that the end (e.g., second end 132 in FIGS. 1 and 2) is above the surface 135 of the substrate 110. For instance, the pins 120 can have a body length 165 of about 1 to 3 times the thickness 167 of the substrate (e.g., substrate 110 in FIG. 2). For example, in some embodiments, when the substrate's thickness 167 equals 0.6 mm then the pin's length 167 is about 2.5 mm.

In some cases, at least one of the pins 120 passes through a hole 125 of the first substrate 110 (FIG. 1, FIG. 3A) or in second substrate (e.g., second substrate 112, FIG. 3B). In other cases, pins 120 can pass through holes 125 in both substrates. Such a configuration can advantageously provide sites for electrical connection on exterior surfaces 135, 315 of both the first and second substrates 110, 112.

In some embodiments, it is preferable for the inorganic sealant 140 to be substantially free of organic material. The presence of certain organic material (e.g., plastics) could permit atmosphere to exchange through the sealant 140 and thereby not permit a sealed chamber 115 to be formed or retained. The term organic material as used herein refers to carbon-containing molecules. The term substantially free as used herein refers to less than about 10 wt % of the organic material.

Some preferred embodiments of the electrically conductive pins 120 are composed of, or include, metal pins. In some cases, the metal pins 120 include copper or bronze plated with nickel, gold, a nickel-gold alloy, or other metals that can facilitate forming a bond when using a metal containing solder as the inorganic sealant. As an example, Au—Ni plated phosphor-bronze pins (e.g., Mill-Max Mfg. Corp., Oyster Bay, N.Y.), and, a gold-tin alloy can be used as the pins 120 and inorganic sealant 140, respectively. In other cases, such as when a melted sintered glass (e.g., glass sponge or glass frit) is used as the inorganic sealant 140, the metal pins 120 are preferable composed a high melting point metal (e.g., melting point of about 1000° C. of higher). In still other cases, however, are low temperature glass seals (e.g., DM2700 glass seal by Dimat, Byfield, Massachusetts, with a melting point of about 320° C.) can be used as the inorganic sealant 140. As an example, tungsten metal pins 120 can be used with a sintered glass inorganic sealant 140 (e.g., Schott Hermes™; NEC Schott Components Corp, Japan) which is melted to form a gas-impervious seal between the pin 120 and the hole 125.

When the first or second substrate 110, 112 is composed of a semi-conducting or conducting material (e.g., silicon or a metal layer) the electrically conductive pins 120 or an electrically conductive inorganic sealant 140 can cause an electrical short-circuit in certain types of electronic devices 105 (e.g., ICs). In these instances, it is desirable for the package 102 to further include an insulating layer 170 (FIG. 2) that electrically isolates the pins 120 and sealant 140 from the first or second substrate 110, 112 that has the holes 125. If the substrate 110 is composed of an insulating material, however, then an additional insulating layer may not be used.

In some embodiments, the insulating layer 170 is or includes silicon oxide, silicon nitride, or silicon oxynitride. In some preferred embodiments the insulating layer 170 conformally coats the entire substrate 110, 112, including the sidewalls 172 of the holes 125 (FIG. 2), to thereby electrically isolate the pins 120 and sealant 140 from the substrate 110, 112.

As illustrated for the embodiment shown in FIG. 1, electrical coupling to the electronic device 105 can include a wire bond 174 between the first ends 130 of the pins and contact pads 175 (e.g., metal pad layers) of the device 105. In other cases, such as shown in FIGS. 3A and 3B, electrical coupling to the electronic device 105 can include a solder ball bond 320 between the first ends 130 of the pins 120 and contact pads 325 on the first substrate 110. The solder ball bonds 320 can be formed into an array to provide multiple points of electrical connection to the device 105, if desired. Metal lines 327 can connect the contact pads 325 to the device 105. In some cases, the orientation of the pins 120 in the holes 125 can be reversed, such that the pins heads 151 (FIG. 2) are inside the cavity 115. In still other cases, an electrical connection between the device 105 and pins 120 can be made be melting pre-deposited solder located on a metal pad (not show) surround around the pin 120 and wire-bonded to the device 105. Based on these examples, one skilled in the art would appreciate additional ways to electrical couple the device 105 to the pins 120.

In some cases, the package 105 can be the entire apparatus 100. In other cases, the apparatus 100 can include other components that the package 105 is directly or indirectly coupled to. For instance, the apparatus 100 can further include a mounting board 180 (e.g., a printed circuit board) having contact structures 182 (e.g. solder balls), and, the second ends 132 of the pins 120 can be electrically coupled to the contact structures 182. Conductive lines or pads 184 on the mounting board 180 can run from the contact structures 182 to other electrical components on the boards 180 (e.g., other device packages, not shown), or, to receptacles 186 to facilitate plugging the apparatus into other electrical apparatuses. Wire bonds, plugs, ball grid arrays 187 or other conventional bonding structures could be used to facilitate electrically coupling.

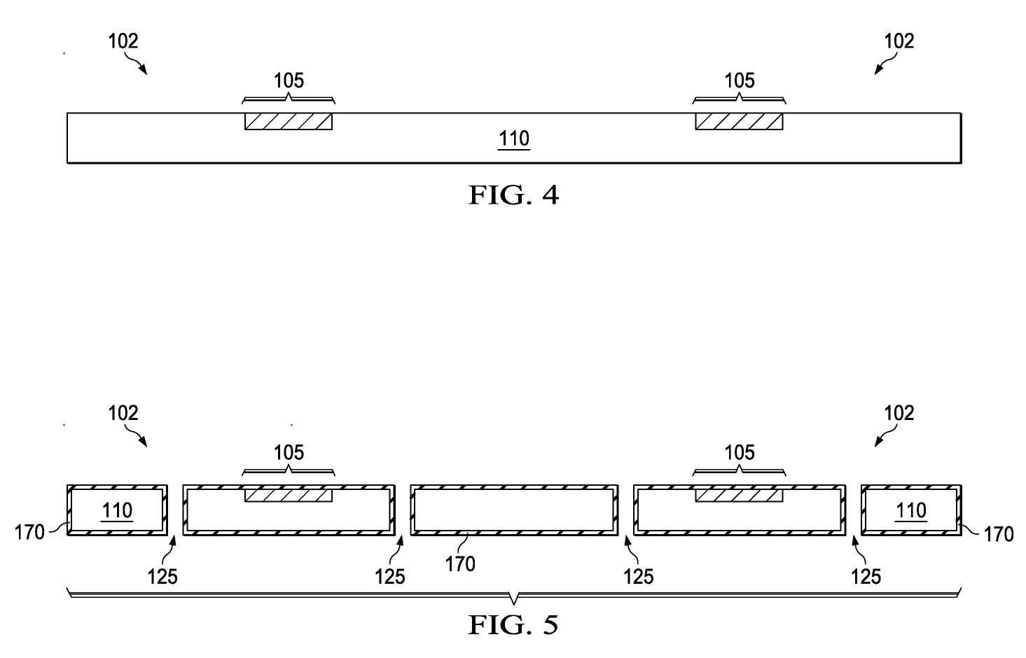

Still another embodiment is a method. In some cases the method comprises manufacturing a sealed electronic device package. Any of the embodiments the apparatuses 100, 300 and packages 102 discussed in the context of FIGS. 1-3 can be manufactured according to the disclosed method. FIGS. 4-10 present cross-sectional and perspective views at selected stages in the manufacture of an example apparatus which includes the manufacture of a sealed electronic device package 102 such as presented in FIGS. 1-3. FIGS. 4-10 show example embodiments of an apparatus that includes example device packages 102.

FIG. 4 shows the package 102 after providing a plurality of electronic devices 105 on a first substrate 110 (e.g., a first planar substrate). In some embodiments, providing the plurality of electronic devices on the first substrate 110 includes fabricating components of each of the devices 105 from the first substrate 110. For instance, a semiconductor wafer substrate 110 (e.g., silicon) can be patterned and implanted with dopants or deposited with materials to form component parts of transistors or other active or passive device components of an IC electronic device (e.g., doped wells, source drain structures, channels, isolation structures). For instance, a metal layer substrate, or, semiconductor or inorganic insulating wafer substrate can be etched or bent to form parts of a MEMS device 105, such as a magnetometer.

In some embodiments, providing the plurality of electronic devices on the first substrate includes mounting prefabricated electronic devices 105 to the first substrate 110. That is, the devices 105 are fabricated in a separate process and then mounted to the substrate 110 (see e.g., FIG. 1). In some cases, for instance, the devices 105 are mounting to the substrate 110 via individual ball-grid solder arrays 187 (FIGS. 1, 3A). In some cases the ball grid array 187 can be formed on the heads of the pins 120 that are passed through the substrate 110 using the procedures as further disclosed herein.

FIG. 5 shows the package 102 after forming a plurality of holes 125 in the first substrate 110. In other embodiments, however, holes 125 can be in a second substrate 112 (e.g., substrate 112, FIG. 3B, also provided as part of the method), and in still other embodiment, holes can be in both of the substrates 110, 112. The holes 125 can be formed by laser drilling, mechanical drilling, reactive ion etching, plasma etching, or other techniques well known to those skilled in the art.

FIG. 5 also shows the package 102 after depositing an insulating layer 170 to conformally coat at least the substrate 110 having the openings 125 in a vicinity of the holes, including sidewalls 172 the holes 125. For instance, a substrate 110 composed of silicon can be place in an oven and heated in an oxygen or nitrogen containing atmosphere at the appropriate temperature and time to form a silicon oxide or silicon nitride insulating layer 170. The insulating layer 170 is made sufficiently thick to ensure that the pins 120 and inorganic sealant 140 (e.g., solder) are electrically isolated from the substrate 110 that has the holes. In some embodiments, the insulating layer 170 is not too thick to substantially changing the shape or dimensions of any structures (e.g., IC, MEMS or OE device structures) on or in the substrate. Alternatively, in other embodiments, the holes 125 can be drilled and the insulating layer 170 formed, before the device 105 is fabricated in or mounted to the substrate 100.

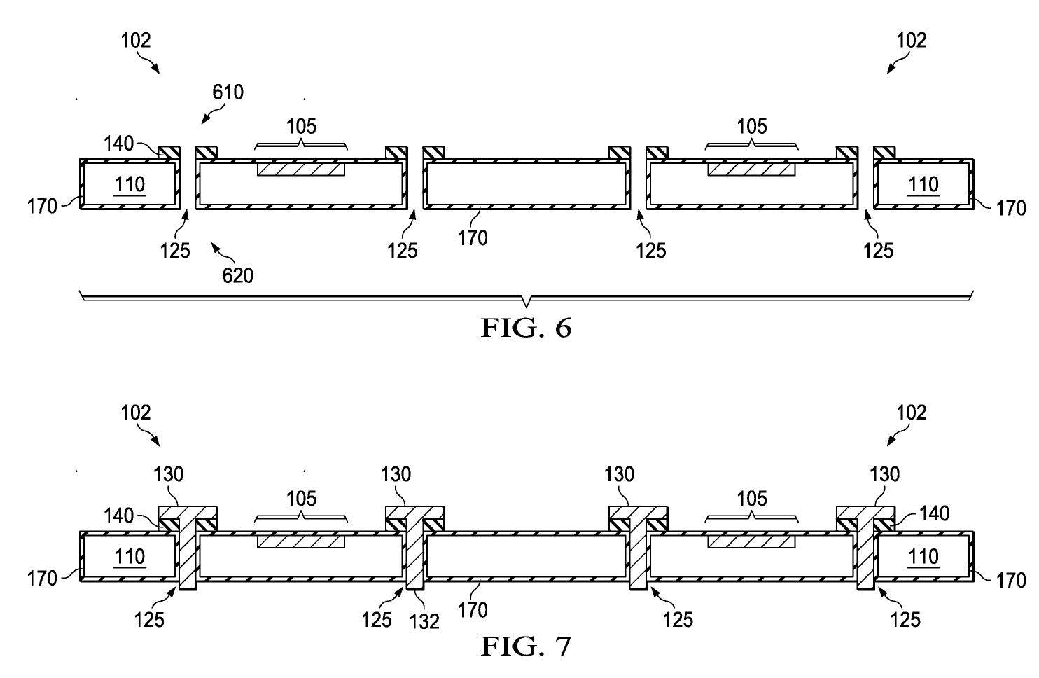

FIG. 6 shows the package 102 after depositing an inorganic sealant 140 on at least one side 610, 620 of the substrate 110 having the holes 125. In some cases it is desirable for the inorganic sealant 140 to be located only in the vicinity of the holes. For instance, if the inorganic sealant 140 is made of an electrically conductive material (e.g., solder) then covering the entire side 610 with sealant 140 could interfere with the operation of the device 105 by causing an electrical short circuit.

For example, in some embodiments, a mask (e.g., a photoresist layer, not shown) can be deposited on the substrate 110 and then patterned using conventional lithographic techniques so that only those portions of the substrate 110 in the vicinity of the holes 125, are exposed through the mask. The exposed portion of the substrate can then be covered with a sealant such as solder by spray coating dip coating or other conventional techniques. Alternatively, the entire surface of the substrate 110 can be cover with the sealant, and then a mask layer is deposited and patterned to remove the mask over all portions of the substrate except in the vicinity of the holes 125. Remaining portions of the mask can then be removed by conventional thermal or chemical methods.

The method can include forming electrically conductive pins that traverse the holes such that a portion of each pin is surrounded by the inorganic sealant.

FIG. 7 shows the package 102 after placing electrically conductive pins 120 through each of the holes 125 such that at least one end of each pin 120 (e.g., the part of the base portion 152 nearest the first end 130) is surrounded by the sealant 140, and the other end of the pin 132 faces an exterior side 135 of the substrate 110 having the holes 125. For instance, automated equipment, such as micromanipulators, can be used to facilitate placing the pins 120 in the holes.

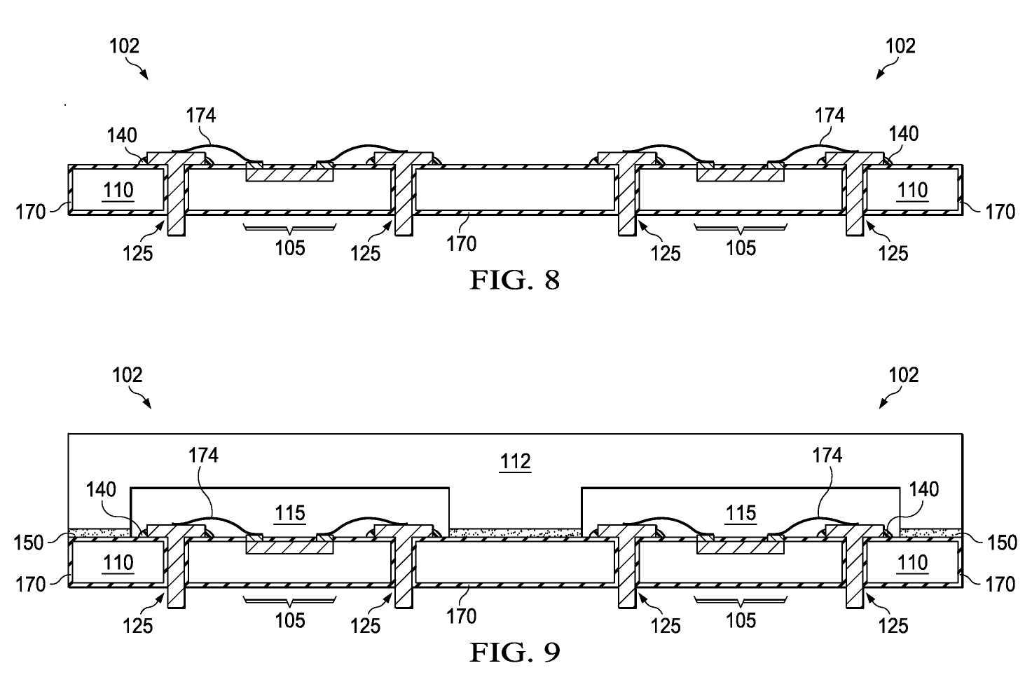

FIG. 8 shows the package 102 after treating the inorganic sealant 140 such that each of the holes 125 are sealed. In some embodiments, treating the sealant 140 includes heating the substrate 110 having the holes 125 (or, in other embodiments substrate 112, FIG. 3B) to melt the sealant 140 and thereby seal the pins 120 to the holes 125. For instance, the substrate 110 can be placed into an oven and heated to melt the inorganic sealant 140. For example when the sealant is a gold-tin solder the substrate 110 can be heated in an oven to a temperature of about 300° C. to melt the solder. Or a sealant 140 composed of glass frit can be can be heated in an oven to a temperature of about 400° C. to melt the glass. In other cases, the sealant 140 of solder can be deposited by well-know evaporation processes around the holes 125, or, a solder preform (e.g., a circular washer of solder) can be placed around the holes 125. The pins 120 can then be placed in the holes 125 so that a least a portion of the pins 110 contact and are surrounded by the sealant 140. Then, the substrate 110 and sealant 140 can be allowed to cool to form the seals around the pins 110.

FIG. 8 further shows the devices 105 after being electrically coupled to the pins 120 that are associated with each package 102. For instance, wire-bound connections 174 can be made between the devices 105 and the pins 120. Or, the device 105 can be mounted on a ball grid array located on the substrate 110. One skilled in the art would appreciate how similar electrical connections can be made between the devices 105 and the pins 120 that pass through the second substrate 112.

Based on the present disclosure, one skilled in the art would appreciate that variations in the above sequence of steps are possible. For example, FIGS. 4-8 depicts the device 105 being fabricated from, or mounted on, the substrate 110 before forming the holes 120, depositing the sealant 140 and placing the pins 120 and treating the sealant 140 to seal the pins 120 to the holes 125. In some embodiments, however, the device 105 is fabricated or mounted after the holes 125 and pins 120 are formed, placed and sealed together. As another example, FIGS. 5 and 6 shows the holes formed and then the sealant 140 deposited. In other cases, however, the sealant 140 can be deposited first and then the holes 125 formed. As another example, holes 125 can be formed in the second substrate 112 (FIG. 3B), instead of, or, in addition, to the first substrate 110, and then pins 120 can be placed in the holes 125 and sealed in a similar fashion to that discussed in the context of FIGS. 5-8.

FIG. 9 shows the package 102 after bonding a second substrate 112 to the first substrate 110 to form individual interior chambers 115 that each house one of the electronic devices 105. In some case, first ends 130 (or second ends 132) of the pins 120 protrude to an exterior of the chamber 115 and second ends 132 (or first ends 130) of the pins 120 make electrical contact with the one or more the electronic device 105, e.g., in the interior of the chamber 115.

Bonding the second substrate 112 to the first substrate 110 can include heating the substrates 110, 112 to melt bonding agents 150 (e.g., composed of solder or sintered glass) deposited on one or both substrates 110, 112. One skilled in the art would understand how to use different types of solder, with different melting points, as the sealant 140 and bonding agent 150, e.g., so that an already formed seal 140 is not disturbed by melting the bonding agent 150. In some embodiments, the substrates 110, 112 are directly bonded together. For instance, in some cases the first and second substrates are anodically bonded together. For example, consider the case when the second substrate 112 is composed of glass, such as Pyrex® glass or other high sodium-content glass, and, the first substrate 110 (or spacer substrate 142 of FIG. 1) is composed of silicon. At elevated temperatures (e.g., about 400° C. or higher), a high voltage (e.g., about 500 Volts of higher) can cause a direct chemical bond (e.g., an anodic bond) to form between such substrates 112, 142. In other cases, however, the additional spacer substrates 142 (FIG. 1) can be anodically bonded to one or both of the substrates 110, 112.

In some preferred embodiments, treating the sealant 140, and, bonding the substrates 110, 112 together, as discussed in the context of FIGS. 7-9, are performed in a vacuum or a predefined atmosphere (e.g., an oxygen-free atmosphere, or, atmosphere containing an inert gas such as helium). The interior chambers 115 are thereby sealed from the external environment surrounding the electronic device package (e.g., air or water).

FIG. 9 also illustrates the second substrate 112 after being shaped to form a portion of the chambers 115. For example, prior to bonding the substrates 110, 112 together, conventional photolithograph and patterned processes can be performed to etch away portions of a second substrate 112 composed of semiconductor or glass, to shape the substrate to have a chamber 115 that is large enough for the device 105 and electrical connection to fit inside. Or, a metallic second substrate 112 can be bent, molded from liquid metal or machined to form the chamber 115.

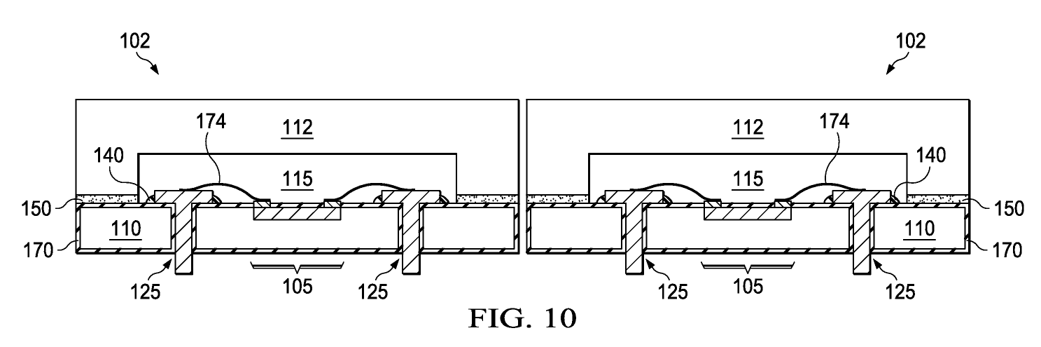

FIG. 10 shows the packages 102 after being dicing the substrates 110, 112 to separate the devices 105 into separate sealed packages 102. Dicing can be achieved by any conventional technique such as sawing or laser cutting.

With continuing reference to FIGS. 4-10, some embodiments of the method comprise providing a first planar substrate 110 with a plurality of electronic devices 105 thereon, and, providing a second planar substrate 112. One of the first and second substrates 110, 112 have a plurality of holes 125 there-through. The method also comprises forming electrically conductive pins 120 that traverse the holes 125 such that a portion of each pin 120 is surrounded by an inorganic sealant 140. The method further comprises bonding the second substrate 112 to the first substrate 110 to form a chamber 115 housing one or more of the electronic devices 105. First ends 130 of the pins 120 protrude to an exterior 125 of the chamber 115 and second ends 132 of the pins 120 make electrical contact with the electronic devices 105.

One skilled in the art would be familiar with additional steps to complete the manufacture of the apparatus. For instance, the method can include further including attaching the package 102 to a mounting board 180 by solder bonding 132 second ends of the pins (e.g., exposed ends of the pins) to contact pads 177 on the board 180 (FIG. 1)

Although some embodiments of the disclosure have been described in detail, those of ordinary skill in the art should understand that they could make various changes, substitutions and alterations herein without departing from the scope of the disclosure.

What is claimed is:

1. An apparatus, comprising:
an electronic device package, including:
an electronic device on a first planar substrate;
a second planar substrate bonded to said first planar substrate so as to form an interior chamber housing said electronic device;
a plurality of electrically conductive pins, each of said pins passing through a hole in one of said first and second planar substrates, wherein:
a first end of each pin is located in said interior chamber and is electrically coupled to said electronic device, and,
a second end of each pin is located on an exterior side of said one of said first and second substrates; and
an inorganic sealant surrounds at least one of said first end or said second end for each of said pin.

2. The apparatus of claim 1, wherein said interior chamber is hermetically-sealed from an external environment surrounding said electronic device package.

3. The apparatus of claim 1, wherein some of said electrically conductive pins pass through holes in said first and second substrates.

4. The apparatus of claim 1, wherein said inorganic sealant includes a glass.

5. The apparatus of claim 1, wherein said inorganic sealant includes a metal-containing solder.

6. The apparatus of claim 1, wherein said electronic device package further includes an insulating layer that electrically isolates said electrically conductive pins from said first or said second substrate having said holes, and, said one of said first and second substrates is a conductive or semiconductive substrate.

7. The apparatus of claim 1, wherein said holes are located in said second substrate.

8. The apparatus of claim 1, wherein portions of said first substrate are components of said electronic device.

9. The apparatus of claim 1, wherein one of said substrates includes a semiconductor layer and the other of said substrates includes a glass layer.

10. The apparatus of claim 1, wherein there is an anodic bond between said first substrate and said second substrate.

11. The apparatus of claim 1, wherein said electrically conductive pins are metal pins.

12. The apparatus of claim 1, wherein said electrical coupling to said electronic device includes a wire bond or a ball bond between said first ends of said pins and contact pads of said electronic device.

13. The apparatus of claim 1, further including a mounting board having contact structures, and wherein said second ends of said pins are electrically coupled to said contact pads.

14. A method, comprising:
providing a first planar substrate with a plurality of electronic devices thereon;
providing a second planar substrate, one of the first and second substrates having a plurality of holes there through;
forming electrically conductive pins that traverse said holes such that a portion of each pin is surrounded by an inorganic sealant ; and
bonding said second substrate to said first substrate to form a chamber housing one or more of said electronic devices, first ends of said pins protruding to an exterior of the chamber and second ends of said pins making electrical contact with the one or more said electronic devices.

15. The method of claim 14, wherein said bonding in a vacuum or predefined atmosphere such that said chamber is sealed from an external environment surrounding said electronic device package.

16. The method of claim 14, wherein said bonding said second substrate to said first substrate includes anodic bonding.

17. The method of claim 14, further including depositing an insulating layer to conformally coat said substrate having said openings in a vicinity of said holes such that said electrically conductive pins and said inorganic sealant are electrically isolated from said substrate having said holes.

18. The method of claim 14, including heating said substrate having said holes to melt said inorganic sealant and thereby form seals around said pins.

19. The method of claim 14, further including dicing said bonded first substrate and second substrate to separate said plurality of electronic devices into separate packages.

20. The method of claim 14, further including attaching said electronic device package to a mounting board by connecting exposed ends of said pins to contact pads on said mounting board.
